(19) United States
(12) Patent Application Publication
(10) Pub. No.: US 2025/0218862 A1
(43) Pub. Date: Jul. 3, 2025

(54) METHOD OF MANUFACTURING DEVICE ISOLATION LAYER AND METHOD OF MANUFACTURING SEMICONDUCTOR DEVICE BY USING THE SAME

(71) Applicant: Samsung Electronics Co., Ltd., Suwon-si (KR)

(72) Inventors: Yunboo JEONG, Suwon-si (KR); Gyuhyun KIL, Suwon-si (KR); Junghoon HAN, Suwon-si (KR)

(73) Assignee: Samsung Electronics Co., Ltd., Suwon-si (KR)

(21) Appl. No.: 18/978,823

(22) Filed: Dec. 12, 2024

(30) Foreign Application Priority Data
Dec. 29, 2023 (KR) 10-2023-0197642

(51) Int. Cl. H01L 21/762; H01L 21/02; H01L 21/311; H10B 12/00

(52) U.S. Cl. CPC H01L 21/76229; H01L 21/02164; H01L 21/02238; H01L 21/0228; H01L 21/31116; H10B 12/09; H10B 12/0335

(57) ABSTRACT

A method incudes forming a trench in a substrate; conformally forming a first insulating layer on a top surface of the substrate and on an inner wall of the trench through a thermal oxidation process; forming a second insulating layer on the first insulating layer through an atomic layer deposition process such that a portion of the second insulating layer is within the trench; performing a dry etching process on the second insulating layer and the first insulating layer such as to expose the top surface of the substrate; and forming a device isolation layer inside the trench, the device isolation layer including a first insulating pattern formed by etching the first insulating layer and a second insulating pattern formed by etching the second insulating layer, wherein the device isolation layer has a round top surface.

### CROSS-REFERENCE TO RELATED APPLICATION

This application is based on and claims priority under 35 U.S.C. § 119 to Korean Patent Application No. 10-2023-0197642, filed on Dec. 29, 2023, in the Korean Intellectual Property Office, the disclosure of which is incorporated by reference herein in its entirety.

### BACKGROUND

### 1. Technical Field

Embodiments of the present disclosure relate to a method of manufacturing a device isolation layer and a method of manufacturing a semiconductor device by using the same, and more particularly, to a method of manufacturing a device isolation layer having a round top surface and a method of manufacturing a semiconductor device using the same.

### 2. Brief Description of Background Art

In accordance with the rapid development of the electronics industry and the needs of users, electronic devices are becoming more compact and lightweight. Accordingly, semiconductor devices with a high degree of integration are required for use in electronic devices, and the design rules for the configurations of semiconductor devices are decreasing. Thus, the difficulty of the manufacturing process for forming conductive patterns and insulating patterns constituting semiconductor devices has gradually been increasing.

### SUMMARY

Embodiments of the present disclosure provide a method of manufacturing a device isolation layer having a round top surface and a method of manufacturing a semiconductor device by using the same.

According to embodiments of the present disclosure, a method is provided and includes: forming a trench in a substrate; conformally forming a first insulating layer on a top surface of the substrate and on an inner wall of the trench through a thermal oxidation process; forming a second insulating layer on the first insulating layer through an atomic layer deposition process such that a portion of the second insulating layer is within the trench; performing a dry etching process on the second insulating layer and the first insulating layer such as to expose the top surface of the substrate; and forming a device isolation layer inside the trench, the device isolation layer including a first insulating pattern formed by etching the first insulating layer and a second insulating pattern formed by etching the second insulating layer, wherein the device isolation layer has a round top surface.

According to embodiments of the present disclosure, a method of manufacturing a semiconductor device is provided and includes: forming a plurality of trenches in each of a cell array area and a peripheral circuit area of a substrate; conformally forming a first insulating layer on inner walls of the plurality of trenches and on a top surface of the substrate through a thermal oxidation process; forming a second insulating layer on the first insulating layer through an atomic layer deposition process such that a portion of the second insulating layer is within the plurality of trenches; forming a plurality of device isolation layers by performing a dry etching process on the second insulating layer and the first insulating layer such as to expose the top surface of the substrate; sequentially forming a high-k dielectric material layer and a conductive material layer on top surfaces of the plurality of device isolation layers and the top surface of the substrate; and patterning the high-k dielectric material layer and the conductive material layer, wherein each of the plurality of device isolation layers formed in the peripheral circuit area have a round top surface.

According to embodiments of the present disclosure, a method of manufacturing a semiconductor device is provided and includes: forming a first device isolation and a second device isolation within a substrate, the substrate including a cell array area including a first active area defined by the first device isolation layer, and a peripheral circuit area including a second active area defined by the second device isolation layer; forming, in the cell array area, a word line crossing the first active area and a direct contact connected to the first active area; forming, in the cell array area, a bit line structure connected to the direct contact and perpendicular to the word line; and forming, in the peripheral circuit area, a peripheral circuit gate structure on the second active area, wherein the forming the first device isolation layer and the second device isolation layer includes: forming trenches in each of the cell array area and the peripheral circuit area; conformally forming a first insulating layer on inner walls of the trenches and a top surface of the substrate through a thermal oxidation process; forming a second insulating layer on the first insulating layer through an atomic layer deposition process such as to fill the trenches; and performing a dry etching process on the second insulating layer and the first insulating layer such as to expose the top surface of the substrate, wherein the first device isolation layer has a flat top surface in the cell array area, and wherein the second device isolation layer has a round top surface in the peripheral circuit area.

Aspects of embodiments of the present disclosure are not limited to those described above, and other aspects that are not mentioned herein will be clearly understood from the following description by those of ordinary skill in the art.

### BRIEF DESCRIPTION OF DRAWINGS

Embodiments will be more clearly understood from the following detailed description taken in conjunction with the accompanying drawings in which:

FIG. 1 is a flowchart of a method of manufacturing a device isolation layer, according to an embodiment;

FIGS. 2 to 7 are cross-sectional views illustrating a process sequence of a method of manufacturing a device isolation layer, according to an embodiment;

FIG. 8 is a graph showing a change in etch amount according to a flow rate ratio of process gas in a dry etching process used in a method of manufacturing a device isolation layer, according to an embodiment;

FIG. 9 is a plan view illustrating a schematic configuration of a semiconductor device according to an embodiment;

FIG. 10 is a planar layout diagram illustrating main elements of a memory cell array area of a semiconductor device, according to an embodiment;

FIGS. 11 to 22 are cross-sectional views illustrating a process sequence of a method of manufacturing a semiconductor device, according to an embodiment; and

FIG. 23 is a configuration diagram illustrating a system including a semiconductor device, according to an embodiment.

### DETAILED DESCRIPTION

Non-limiting example embodiments of the present disclosure will be described in detail below with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

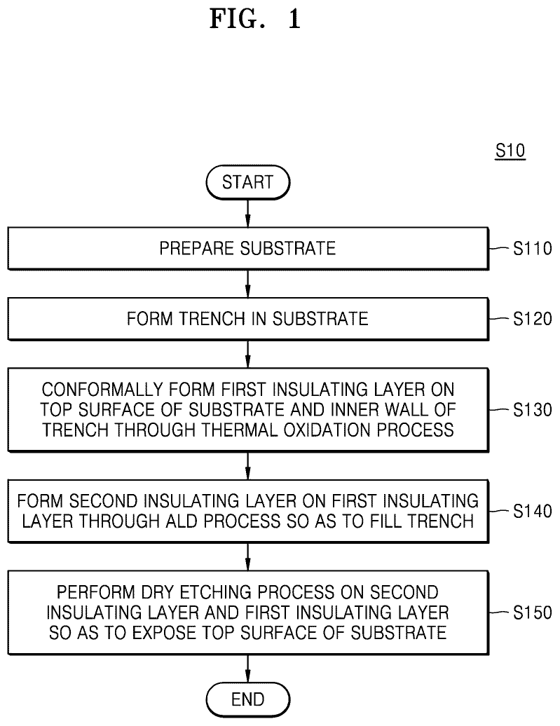

FIG. 1 is a flowchart of a method of manufacturing a device isolation layer, according to an embodiment.

Referring to FIG. 1, a method S10 of manufacturing a device isolation layer may include a process sequence of a first operation S110, a second operation S120, a third operation S130, a fourth operation S140, and a fifth operation S150.

When a certain embodiment is implemented differently, a specific process sequence may be performed differently from a sequence described herein. For example, two consecutively described processes may be performed substantially at the same time or performed in an order opposite to the described order.

The method S10 of manufacturing a device isolation layer, according to an embodiment of the present disclosure, may include the first operation S110 of preparing a substrate, the second operation S120 of forming a trench in the substrate, the third operation S130 of conformally forming a first insulating layer on a top surface of the substrate and an inner wall of the trench through a thermal oxidation process, the fourth operation S140 of forming a second insulating layer on the first insulating layer through an atomic layer deposition (ALD) process so as to fill the trench, and the fifth operation S150 of performing a dry etching process on the second insulating layer and the first insulating layer so as to expose the top surface of the substrate.

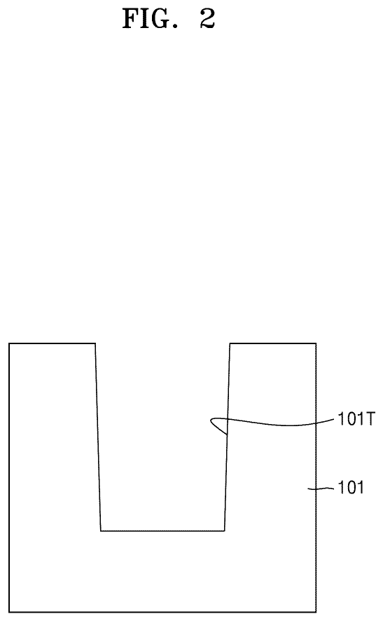

Aspects of the first operation S110, the second operation S120, the third operation S130, the fourth operation S140, and the fifth operation S150 are described in detail below with reference to FIGS. 2 to 7.

FIGS. 2 to 7 are cross-sectional views illustrating a process sequence of a method of manufacturing a device isolation layer, according to an embodiment.

Referring to FIG. 2, an etching process of forming a trench 101T in a substrate 101 may be performed.

The trench 101T may be formed by forming a mask pattern on the substrate 101 and etching the substrate 101 by using the mask pattern as an etch mask. The etching may be dry etching (e.g., plasma etching).

Due to the characteristics of the dry etching process, the width of the trench 101T may become narrower toward the bottom of the trench 101T. Accordingly, a sidewall of the trench 101T may not be vertical but may have a tapered shape with a slight inclination. Although one trench 101T is illustrated, embodiments of the present disclosure are not limited thereto. That is, a plurality of the trench 101T may be formed in the substrate 101.

Subsequently, the mask pattern may be completely removed from the substrate 101 by ashing and stripping processes.

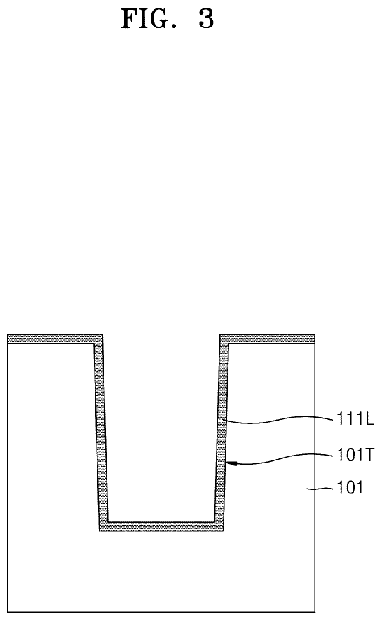

Referring to FIG. 3, a first insulating layer 111L may be conformally formed on the top surface of the substrate 101 and the inner wall of the trench 101T.

The first insulating layer 111L may be a silicon oxide layer formed through a thermal oxidation process. The first insulating layer 111L formed through the thermal oxidation process may have excellent interface characteristics with respect to the substrate 101, and the quality of the silicon oxide layer may be excellent.

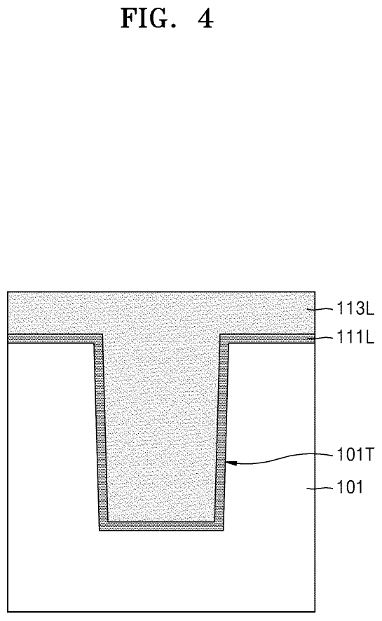

Referring to FIG. 4, a second insulating layer 113L may be formed on the first insulating layer 111L through an ALD process so as to fill the trench 101T.

The second insulating layer 113L may be a silicon oxide layer formed through an ALD process. The second insulating layer 113L formed through the ALD process may be formed to be thick and may have relatively excellent step coverage, and the quality of the silicon oxide layer may be excellent.

The first insulating layer 111L and the second insulating layer 113L may be manufactured through different processes but may be formed of the same material. That is, both the first insulating layer 111L and the second insulating layer 113L may be silicon oxide layers.

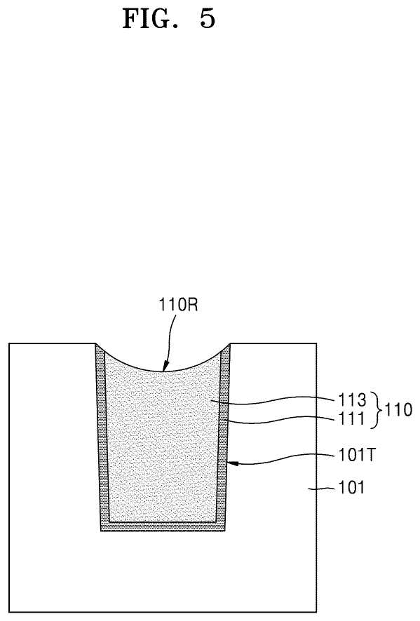

Referring to FIG. 5, the second insulating layer 113L (see FIG. 4) and the first insulating layer 111L (see FIG. 4) may be dry-etched to expose the top surface of the substrate 101.

The dry etching may be performed in a process condition where a second etch rate of the second insulating layer 113L (see FIG. 4) is greater than a first etch rate of the first insulating layer 111L (see FIG. 4). That is, the dry etching may be performed in a single process condition using a selectivity ratio of the first etch rate of the first insulating layer 111L (see FIG. 4) to the second etch rate of the second insulating layer 113L (see FIG. 4).

In the dry etching process, the first etch rate of the first insulating layer 11L (see FIG. 4) and the second etch rate of the second insulating layer 113L (see FIG. 4) may be controlled by the flow rate of process gas used in the process condition. The process gas may include fluorine (HF) gas and ammonia (NH₃) gas. As described below, the dry etching may be performed in a condition where the flow rate of the HF gas is greater than the flow rate of the NH₃ gas.

Through the dry etching, the first insulating layer 111L (see FIG. 4) may be formed as a first insulating pattern 111 and the second insulating layer 113L (see FIG. 4) may be formed as a second insulating pattern 113.

Accordingly, a device isolation layer 110 may be formed in the substrate 101. The device isolation layer 110 may include the first insulating pattern 111 on an outer side and the second insulating pattern 113 on an inner side. The device isolation layer 110 may be a shallow trench isolation, but embodiments of the present disclosure are not limited thereto.

In addition, although one device isolation layer 110 is illustrated, embodiments of the present disclosure are not limited thereto. That is, a plurality of the device isolation layer 110 may be formed in the substrate 101.

In some embodiments, due to the dry etching, a vertical level of the top surface of the first insulating pattern 111 may be higher than a vertical level of the top surface of the second insulating pattern 113 in the device isolation layer 110.

In some embodiments, the device isolation layer 110 may have a round top surface 110R due to the dry etching. The round top surface 110R of the device isolation layer 110 may be formed continuously with an approximately constant curvature through the outermost edge of the first insulating pattern 111, the interface between the first insulating pattern 111 and the second insulating pattern 113, and the second insulating pattern 113.

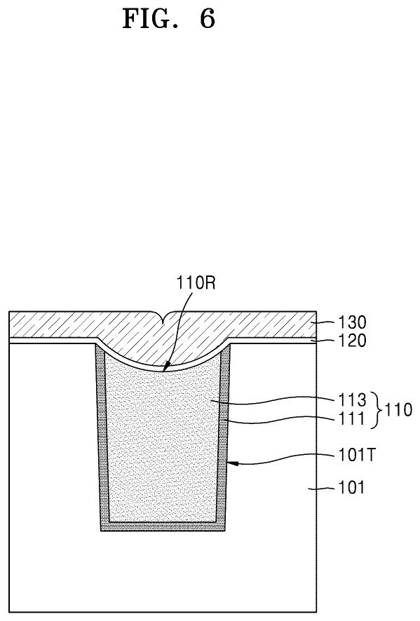

Referring to FIG. 6, a high-k dielectric material layer 120 and a conductive material layer 130 may be sequentially formed on the top surface of the device isolation layer 110 and the top surface of the substrate 101.

First, the high-k dielectric material layer 120 may be formed to conformally cover the top surface of the device isolation layer 110 and the top surface of the substrate 101. The high-k dielectric material layer 120 may be formed to be flat on the top surface of the substrate 101 and may be formed to be round on the top surface of the device isolation layer 110.

The high-k dielectric material layer 120 may have a dielectric constant higher than a dielectric constant of the silicon oxide layer. For example, the high-k dielectric material layer 120 may have a dielectric constant of about 10 to about 25.

In some embodiments, the high-k dielectric material layer 120 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO).

Subsequently, the conductive material layer 130 may be formed to cover the top surface of the high-k dielectric material layer 120. The conductive material layer 130 may be formed to be flat on the top surface of the substrate 101 and may be formed to have a convex portion on the top surface of the device isolation layer 110. The conductive material layer 130 may be formed to be thicker than the high-k dielectric material layer 120.

For example, the conductive material layer 130 may include doped polysilicon, TiN, TiSiN, W, tungsten silicide, or any combination thereof, but embodiments of the present disclosure are not limited thereto.

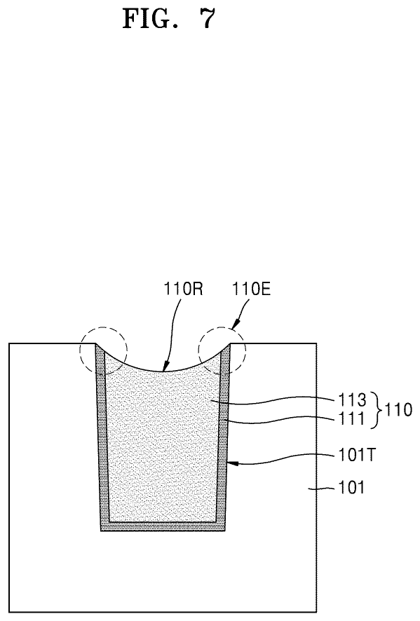

Referring to FIG. 7, the high-k dielectric material layer 120 (see FIG. 6) and the conductive material layer 130 (see FIG. 6) may be removed from the top surface of the device isolation layer 110 and the top surface of the substrate 101 adjacent to the device isolation layer 110.

In order to form a gate structure by patterning the high-k dielectric material layer 120 (see FIG. 6) and the conductive material layer 130 (see FIG. 6), the high-k dielectric material layer 120 (see FIG. 6) and the conductive material layer 130 (see FIG. 6) may be etched from the top surface of the device isolation layer 110 and the top surface of the substrate 101 adjacent to the device isolation layer 110.

In the etching process, since the device isolation layer 110 according to an embodiment of the present disclosure has the round top surface 110R, the vertical thickness of the conductive material layer 130 (see FIG. 6) located on an edge top surface 110E of the device isolation layer 110 may be relatively small. Accordingly, embodiments of the present disclosure may have an effect that unwanted residue of the conductive material layer 130 (see FIG. 6) does not remain on the top surface of the device isolation layer 110 in subsequent processes. In other words, an additional process may not be performed so as to remove unwanted residue of the conductive material layer 130 (see FIG. 6) from the edge top surface 110E of the device isolation layer 110.

Ultimately, in the method of manufacturing the device isolation layer 110, according to an embodiment of the present disclosure, the device isolation layer 110 that includes the first insulating pattern 111 and the second insulating pattern 113 formed by different manufacturing methods e.g., (the thermal oxidation process and the ALD process) and has the round top surface 110R may be formed on the substrate 101, and thus, it may be expected that unwanted residue of the conductive material layer 130 (see FIG. 6) does not remain on the top surface of the device isolation layer 110 in subsequent processes.

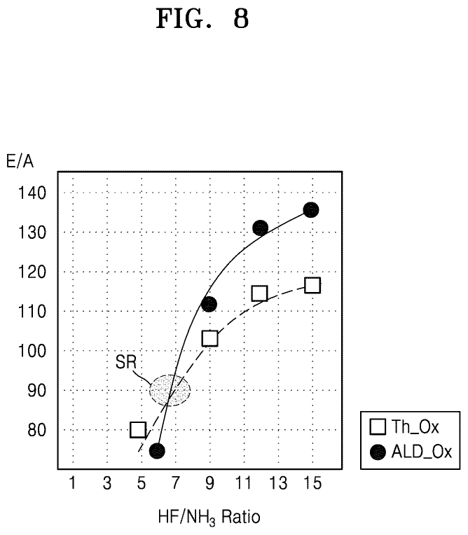

FIG. 8 is a graph showing a change in etch amount according to a flow rate ratio of process gas in a dry etching process used in a method of manufacturing a device isolation layer, according to an embodiment.

In the graph of FIG. 8, the X-axis represents a ratio of HF gas to NH₃ gas and the Y-axis represents an etch amount E/A of each insulating layer. Since the Y-axis refers to an etch amount for the same time, the etch amount may be interpreted as a concept corresponding to an etch rate. In addition, the etch amount E/A is an arbitrary unit representing a relative value and is not an absolute value.

A first etch rate of a first insulating layer Th_Ox to a second etch rate of a second insulating layer ALD_Ox may be controlled during a dry etching process. Specifically, the etch rate may be controlled by a relative flow rate of process gas used in the process condition of the dry etching process, and the process gas may include HF gas and NH₃ gas.

For example, when the ratio of the flow rate of the HF gas to the flow rate of the NH₃ gas on the X axis is about 6, the second etch rate of the second insulating layer ALD_Ox may be lower than the first etch rate of the first insulating layer Th_Ox.

In contrast, when the ratio of the flow rate of the HF gas to the flow rate of the NH₃ gas on the X axis is about 7, the second etch rate of the second insulating layer ALD_Ox may be higher than the first etch rate of the first insulating layer Th_Ox.

That is, there may be a section SR where a selectivity ratio of the first insulating layer Th_Ox to the second insulating layer ALD_Ox is reversed, depending on the ratio of the flow rate of the HF gas to the flow rate of the NH₃ gas. The inventors found that, when dry etching was performed on a material constituting the device isolation layer 110 (see FIG. 4) in the section SR where the selectivity ratio is reversed, a result similar to that when wet etching was performed may be obtained.

In this manner, the device isolation layer 110 (see FIG. 4) having the round top surface 110R (see FIG. 4) may be formed by using the dry etching process in which the first insulating layer Th_Ox and the second insulating layer ALD_Ox formed by different manufacturing methods (e.g., the thermal oxidation process and the ALD process) are etched at different etch rates.

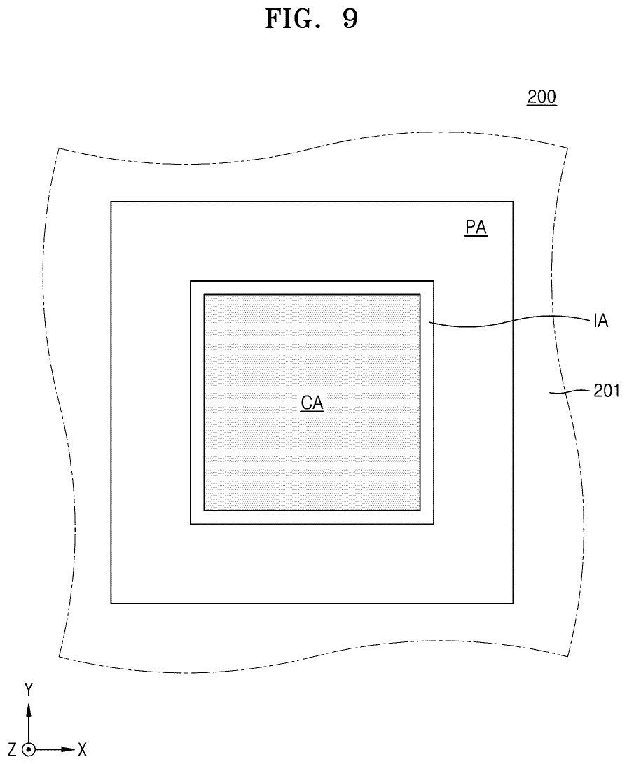

FIG. 9 is a plan view illustrating a schematic configuration of a semiconductor device according to an embodiment.

Referring to FIG. 9, a semiconductor device 200 may have a cell array area CA, a peripheral circuit area PA surrounding the cell array area CA, and an interface area IA arranged between the cell array area CA and the peripheral circuit area PA.

A substrate 201 may be a Si-containing wafer. In some embodiments, the substrate 201 may be a wafer including a semiconductor element, such as germanium (Ge), or a compound semiconductor, such as silicon carbide (SiC), gallium arsenide (GaAs), indium arsenide (InAs), and indium phosphide (InP). In some embodiments, the substrate 201 may have a silicon-on-insulator (SOI) structure. In addition, the substrate 201 may include a conductive area, for example, a dopant-doped well or a dopant-doped structure.

In some embodiments, the cell array area CA may be a memory cell array area of the semiconductor device 200. The cell array area CA may constitute a memory cell array area of a volatile memory device or a memory cell array area of a non-volatile memory device. The memory cell array area may be a memory cell array area of dynamic random access memory (DRAM), magnetic RAM (MRAM), static RAM (SRAM), phase-change RAM (PRAM), resistance RAM (RRAM), or ferroelectric RAM (FRAM). The cell array area CA may include a unit memory cell having a transistor and a capacitor or a unit memory cell having a switching element and a variable resistor.

Peripheral circuits that drive memory cells located in the cell array area CA may be arranged in the peripheral circuit area PA.

A plurality of conductive lines for electrical connection between the cell array area CA and the peripheral circuit area PA and an insulating structure for insulation between the cell array area CA and the peripheral circuit area PA may be arranged in the interface area IA.

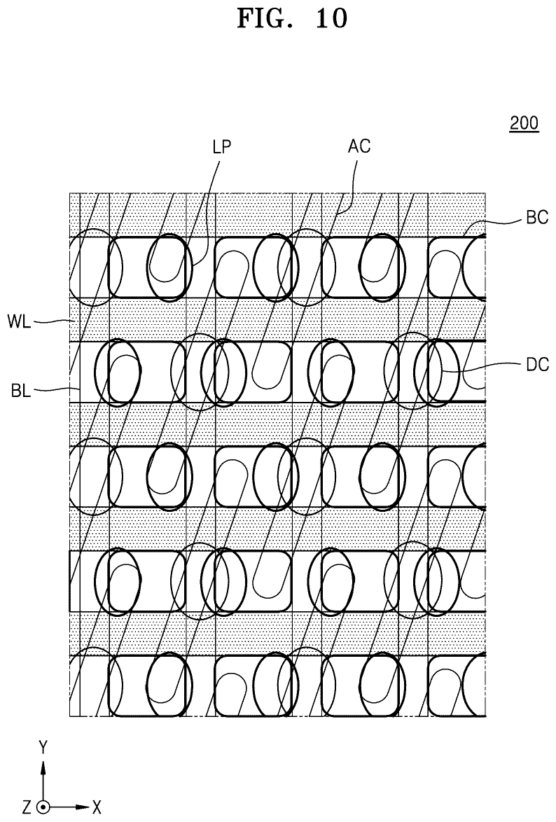

FIG. 10 is a planar layout diagram illustrating main elements of a memory cell array area of a semiconductor device, according to an embodiment.

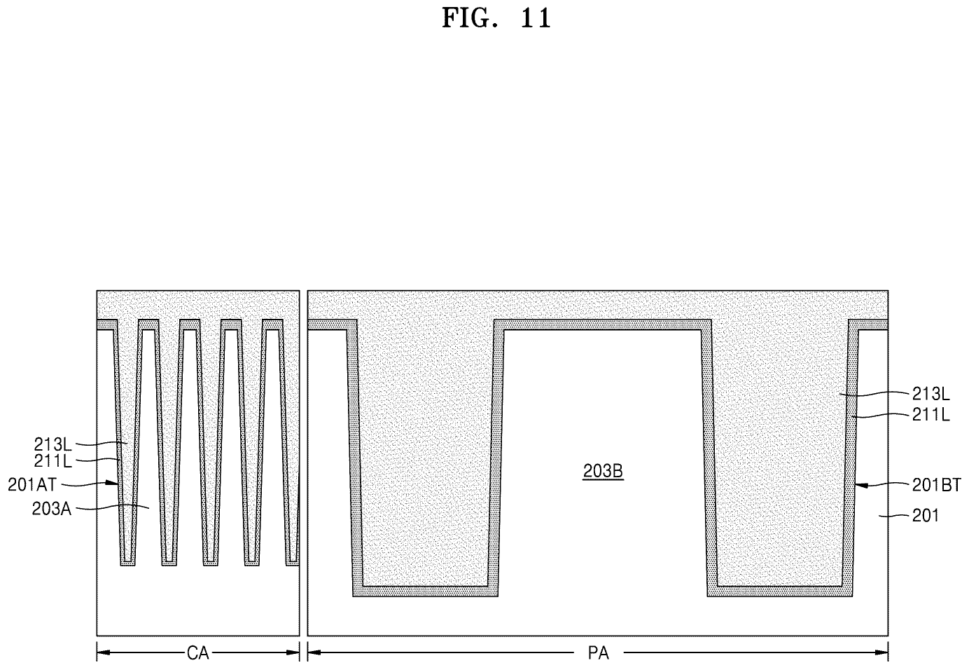

Referring to FIG. 10, a semiconductor device 200 may include a plurality of first active areas 203A (see FIG. 11) arranged to have a long axis in a diagonal direction with respect to the first direction (the X direction) and the second direction (the Y direction).

In the present specification, an active area formed in a cell array area CA including the semiconductor device 200 may be referred to as one of the first active areas 203A (see FIG. 11), and an active area formed in a peripheral circuit area PA (see FIG. 11) other than the cell array area CA may be referred to as one of the second active areas 203B (see of FIG. 11).

A plurality of word lines WL may extend parallel to each other in the first direction (the X direction) across the first active areas 203A (see FIG. 11). A plurality of bit lines BL may extend parallel to each other on the word lines WL in the second direction (the Y direction) crossing the first direction (the X direction).

The bit lines BL may be respectively connected to the first active areas 203A (see FIG. 11) through direct contacts DC. In some embodiments, a plurality of buried contacts BC may be formed between two neighboring ones of the bit lines BL. Each of the buried contacts BC may extend to the upper portion of one of the two neighboring ones of the bit lines BL. In some embodiments, the buried contacts BC may be arranged in a row in the first direction (the X direction) and the second direction (the Y direction).

A plurality of landing pads LP may be respectively formed on the buried contacts BC. The buried contacts BC and the landing pads LP may connect lower electrodes of capacitors formed on the upper portions of the bit lines BL to the first active areas 203A (see FIG. 11). The landing pads LP may be respectively arranged to partially overlap the buried contacts BC.

FIGS. 11 to 22 are cross-sectional views illustrating a process sequence of a method of manufacturing a semiconductor device, according to an embodiment.

Referring to FIG. 11, a first insulating layer 211L may be conformally formed on an inner wall of a first trench 201AT in a cell array area CA, an inner wall of a second trench 201BT in a peripheral circuit area PA, and a top surface of a substrate 201.

The first insulating layer 211L may be a silicon oxide layer formed through a thermal oxidation process. The first insulating layer 211L formed through the thermal oxidation process may have excellent interface characteristics with respect to the substrate 201, and the quality of the silicon oxide layer may be excellent.

Subsequently, a second insulating layer 213L, which is a silicon oxide layer formed through an ALD process, may be formed on the first insulating layer 211L so as to fill the first trench 201AT and the second trench 201BT.

The first insulating layer 211L and the second insulating layer 213L may be manufactured through different processes but may be formed of the same material. That is, both the first insulating layer 211L and the second insulating layer 213L may be silicon oxide layers.

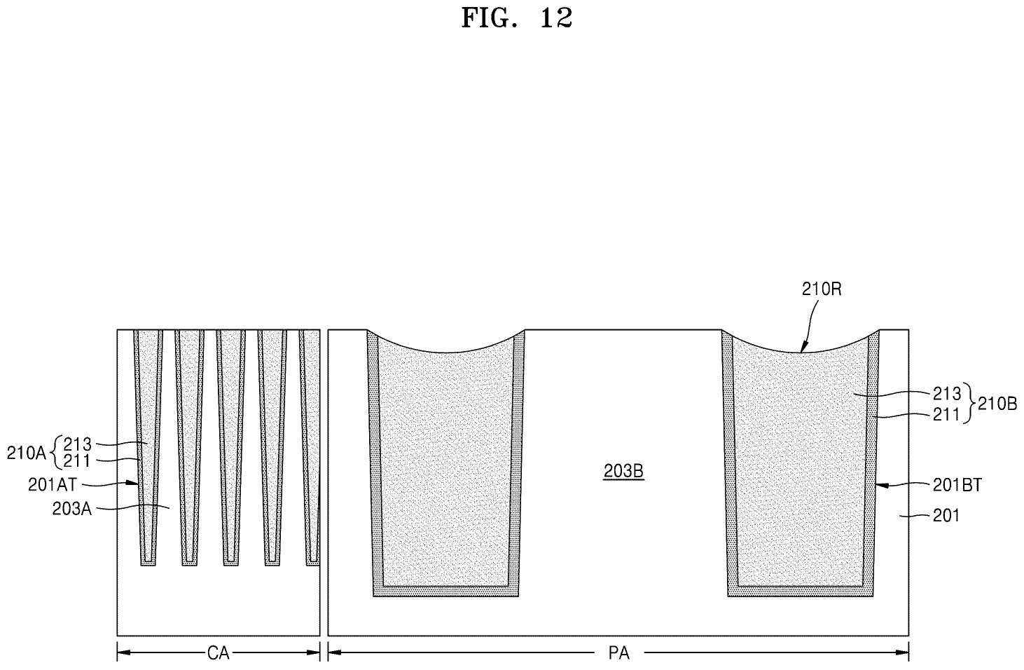

Referring to FIG. 12, the second insulating layer 213L (see FIG. 11) and the first insulating layer 211L (see FIG. 11) may be dry-etched to expose the top surface of the substrate 201.

The dry etching may be performed in a process condition where a second etch rate of the second insulating layer 213L (see FIG. 11) is greater than a first etch rate of the first insulating layer 211L (see FIG. 11). That is, the dry etching may be performed in a single process condition using a selectivity ratio of the first etch rate of the first insulating layer 211L (see FIG. 11) to the second etch rate of the second insulating layer 213L (see FIG. 11).

Through the dry etching, the first insulating layer 211L (see FIG. 11) may be formed as a first insulating pattern 211 and the second insulating layer 213L (see FIG. 11) may be formed as a second insulating pattern 213.

Accordingly, a first device isolation layer 210A may be formed in the cell array area CA and a second device isolation layer 210B may be formed in the peripheral circuit area PA. Each of the first device isolation layer 210A and the second device isolation layer 210B may include the first insulating pattern 211 on the outer side and the second insulating pattern 213 on the inner side.

A second width of the second device isolation layer 210B in the horizontal direction in the peripheral circuit area PA may be greater than a first width of the first device isolation layer 210A in the horizontal direction in the cell array area CA. Accordingly, the second device isolation layer 210B may have a relatively round top surface 210R, compared to the first device isolation layer 210A.

The first device isolation layer 210A and the second device isolation layer 210B may each be a shallow trench isolation, but embodiments of the present disclosure are not limited thereto.

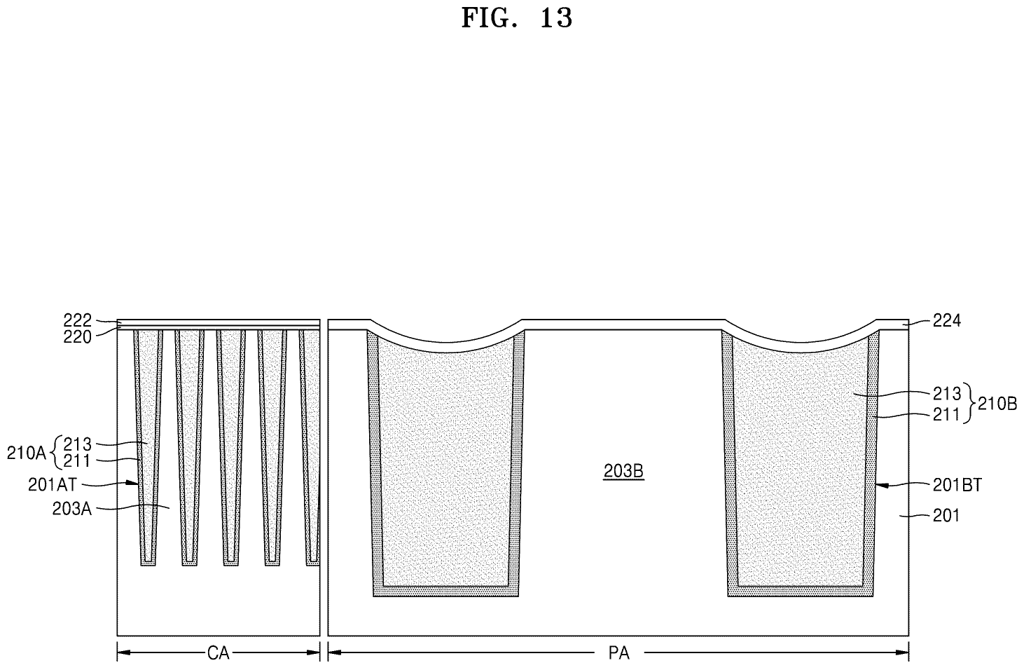

Referring to FIG. 13, a first active area 203A may be defined in the cell array area CA by the first device isolation layer 210A and a second active area 203B may be defined in the peripheral circuit area PA by the second device isolation layer 210B.

A plurality of word line trenches may be formed in the substrate 201 in the cell array area CA. The word line trenches may extend parallel to each other in the first direction (see the X direction of FIG. 10) and may each have a line shape crossing the first active area 203A.

A plurality of gate dielectric layers, a plurality of word lines WL (see FIG. 10), and a plurality of buried insulating layers may be sequentially formed inside the word line trenches. The top surfaces of the buried insulating layers may be located at substantially the same level as the top surface of the substrate 201.

In some embodiments, after the word lines WL are formed, source/drain regions may be formed on the top surfaces of the first active areas 203A by implanting dopants into the substrate 201 from both sides of the word lines WL. In some embodiments, a dopant implantation process for forming source/drain regions may be performed before the word lines WL are formed.

A first surface insulating layer 220 and a second surface insulating layer 222 may be sequentially formed on the substrate 201 in the cell array area CA and the peripheral circuit area PA. Then, the second active areas 203B of the substrate 201 may be exposed again by removing the first surface insulating layer 220 and the second surface insulating layer 222 in the peripheral circuit area PA. Subsequently, a gate dielectric layer 224 may be formed on the substrate 201 in the peripheral circuit area PA in a state in which the cell array area CA is covered with a mask pattern.

The first surface insulating layer 220 may include a silicon oxide layer and the second surface insulating layer 222 may include a silicon nitride layer, but embodiments of the present disclosure are not limited thereto. Before the formation of the gate dielectric layer 224, impurities may be removed from the surface of the substrate 201 in the peripheral circuit area PA through the formation and removal of the first surface insulating layer 220 and the second surface insulating layer 222 in the peripheral circuit area PA. Accordingly, the quality of the gate dielectric layer 224 in the peripheral circuit area PA may be improved.

The gate dielectric layer 224 may include at least one selected from among a silicon oxide layer, a silicon nitride layer, a silicon oxynitride layer, an oxide/nitride/oxide (ONO) layer, and a high-k dielectric material layer having a higher dielectric constant than a silicon oxide layer. For example, the gate dielectric layer 224 may have a dielectric constant of about 10 to about 25.

In some embodiments, the gate dielectric layer 224 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO).

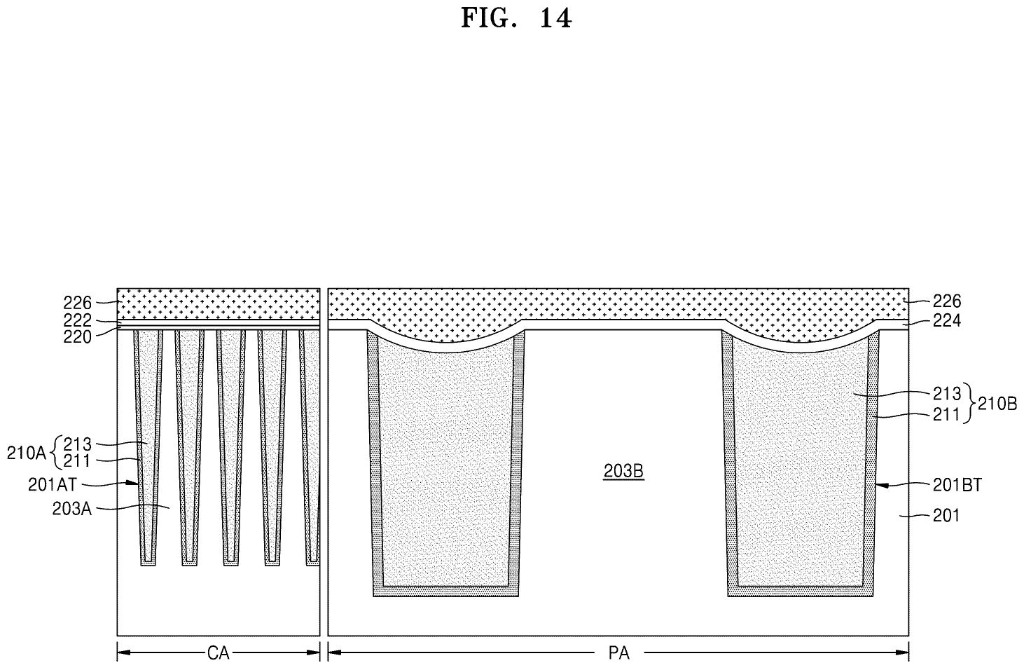

Referring to FIG. 14, a first conductive layer 226 may be formed on the substrate 201 in the cell array area CA and the peripheral circuit area PA.

The first conductive layer 226 may include doped polysilicon, but embodiments of the present disclosure are not limited thereto.

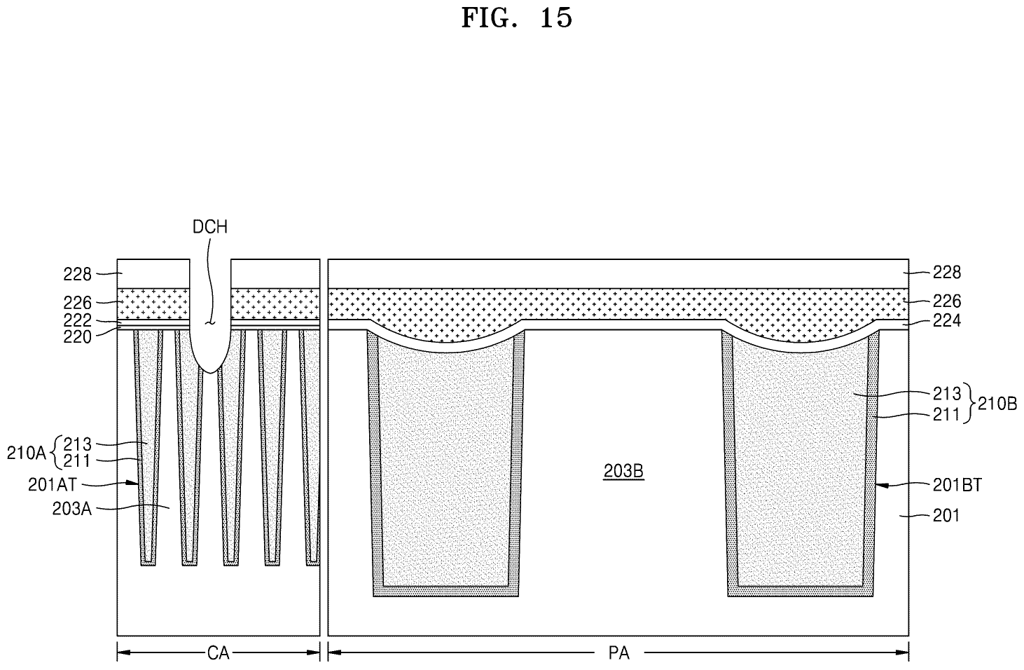

Referring to FIG. 15, a mask pattern 228 may be formed on the first conductive layer 226 in the cell array area CA and the peripheral circuit area PA.

An opening partially exposing the first conductive layer 226 in the cell array area CA may be formed in the mask pattern 228. In the peripheral circuit area PA, the first conductive layer 226 may be covered with the mask pattern 228 so as not to be exposed to the outside.

Subsequently, the first conductive layer 226 exposed through the opening of the mask pattern 228 may be etched. A portion of the substrate 201 and a portion of the first device isolation layer 210A, which are exposed by the etching, may be etched to form a direct contact hole DCH exposing the first active area 203A of the substrate 201 in the cell array area CA.

The mask pattern 228 may be a hard mask pattern including a silicon oxide layer or a silicon nitride layer. A photolithography process may be used to form the mask pattern 228.

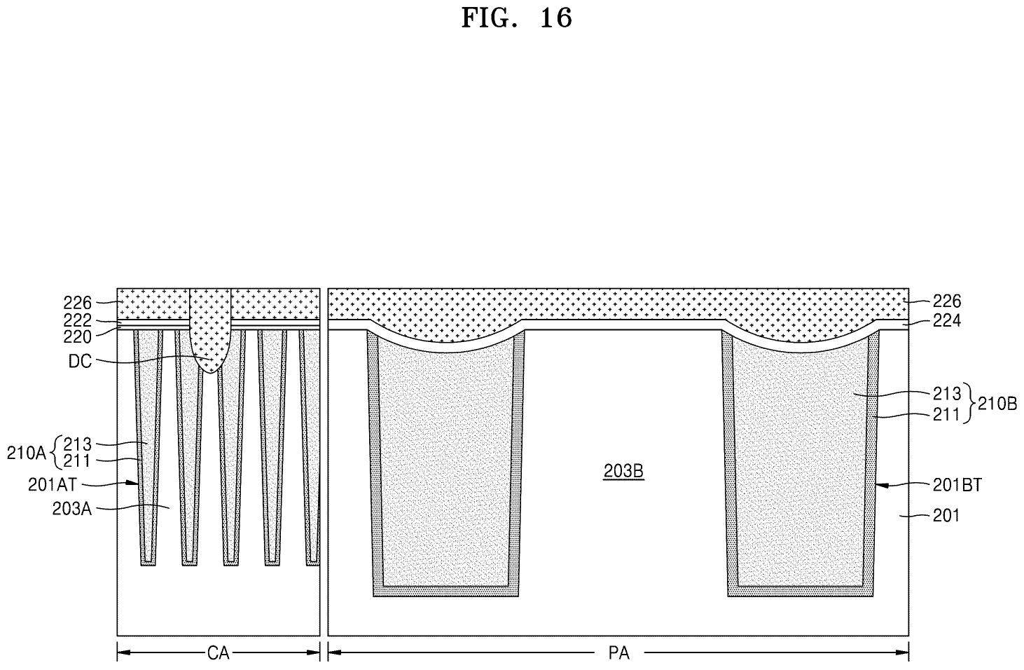

Referring to FIG. 16, after the mask pattern 228 is removed, a second conductive layer having a thickness sufficient to fill the direct contact hole DCH may be formed inside the direct contact hole DCH and on the first conductive layer 226.

By etching back the second conductive layer so that the second conductive layer remains only inside the direct contact hole DCH, a direct contact DC including the second conductive layer remaining inside the direct contact hole DCH may be formed. The second conductive layer may include doped polysilicon, but embodiments of the present disclosure are not limited thereto.

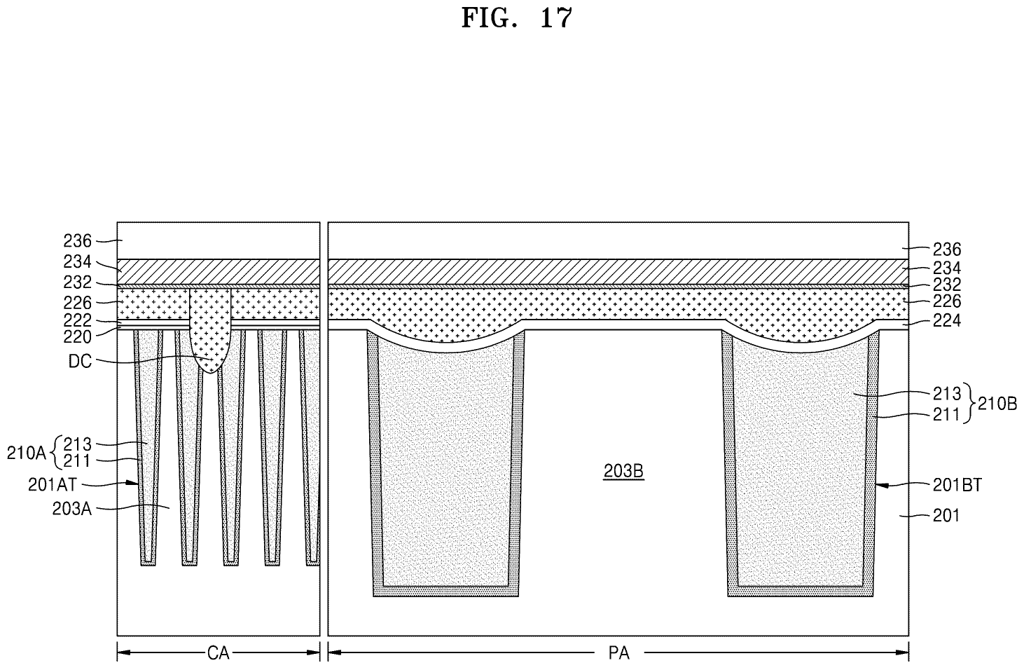

Referring to FIG. 17, a third conductive layer 232, a fourth conductive layer 234, and a capping layer 236 may be sequentially formed on the first conductive layer 226 and the direct contact DC in the cell array area CA and the peripheral circuit area PA.

The third conductive layer 232 and the fourth conductive layer 234 may each include TiN, TiSiN, W, tungsten silicide, or any combination thereof, but embodiments of the present disclosure are not limited thereto. In some embodiments, the third conductive layer 232 may include TiSiN and the fourth conductive layer 234 may include W. The capping layer 236 may include a silicon nitride layer.

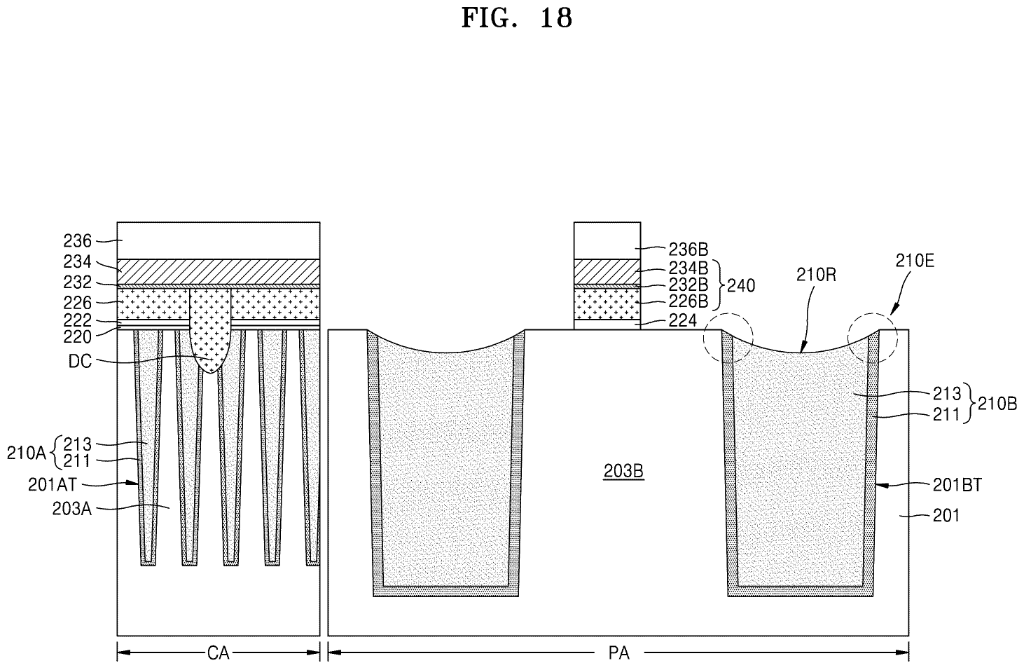

Referring to FIG. 18, the gate dielectric layer 224, the first conductive layer 226, the third conductive layer 232, the fourth conductive layer 234, and the capping layer 236 may be patterned in the peripheral circuit area PA in a state in which the cell array area CA is covered with the mask pattern.

A gate electrode 240 for a peripheral circuit, including a first conductive pattern 226B, a third conductive pattern 232B, and a fourth conductive pattern 234B, which are formed as the result of the patterning, may be formed on the gate dielectric layer 224 in the peripheral circuit area PA. The gate electrode 240 may be covered with a capping pattern 236B.

In the patterning process, since the second device isolation layer 210B according to an embodiment of the present disclosure has a round top surface 210R, the thickness of the first conductive layer 226, the third conductive layer 232, and/or the fourth conductive layer 234 located on the edge top surface 210E of the second device isolation layer 210B in the vertical direction may be relatively small.

Accordingly, embodiments of the present disclosure have an effect that unwanted residue of the first conductive layer 226, the third conductive layer 232, and/or the fourth conductive layer 234 does not remain on and around the second device isolation layer 210B. In other words, an additional process for removing unwanted residue of the first conductive layer 226, the third conductive layer 232, and/or the fourth conductive layer 234 may not be performed on and around the edge top surface 210E of the second device isolation layer 210B.

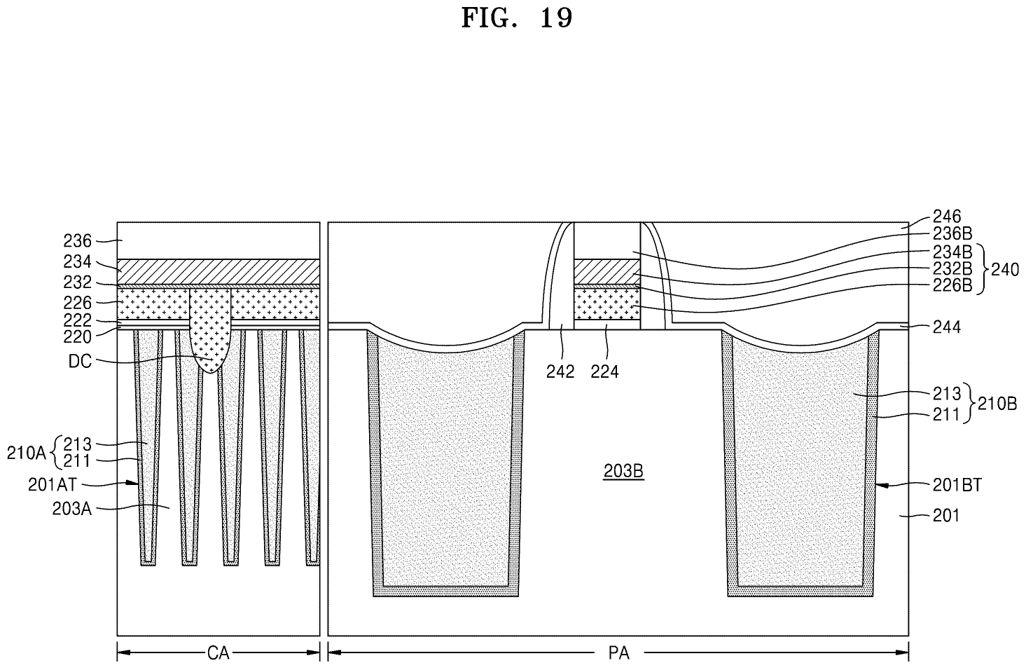

Referring to FIG. 19, insulating spacers 242 may be formed on both sidewalls of the gate structure including the stacked structure of the gate dielectric layer 224, the gate electrode 240, and the capping pattern 236B, and then, an insulating thin-film 244 may be formed on an entire surface of the peripheral circuit area PA so as to cover the gate structure.

The insulating spacers 242 may each include a silicon oxide layer, a silicon nitride layer, or any combination thereof and the insulating thin-film may include a silicon nitride layer, but embodiments of the present disclosure are not limited thereto.

Subsequently, a interlayer insulating layer 246, that is planarized, is formed to cover the gate structure and the insulating thin-film 244. The interlayer insulating layer 246 may include a silicon oxide layer formed by a high density plasma (HDP) process or a flowable chemical vapor deposition (FCVD) process, but embodiments of the present disclosure are not limited thereto.

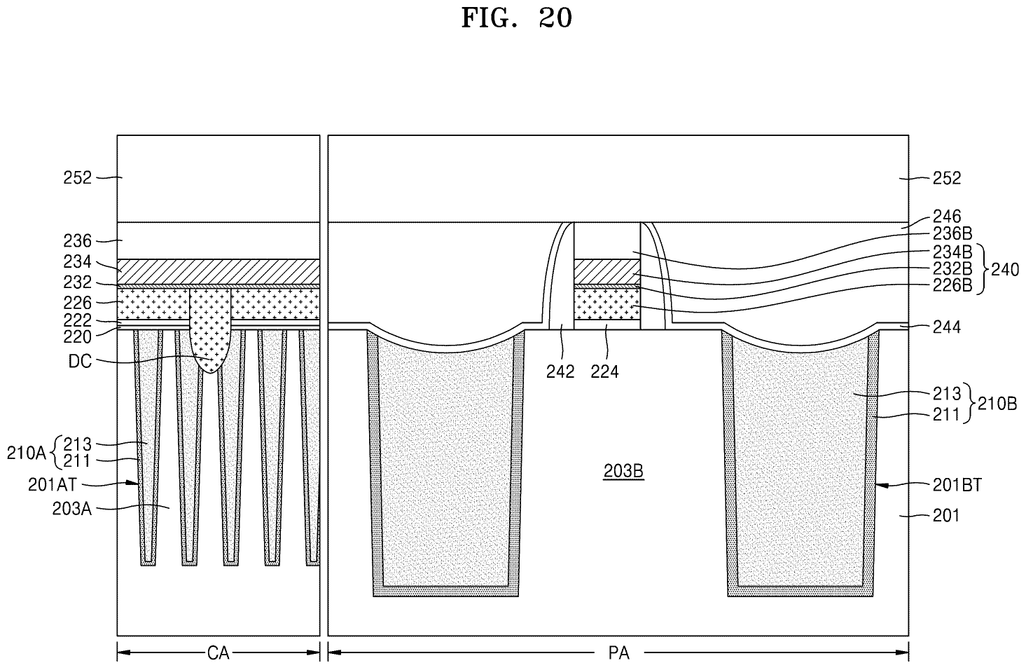

Referring to FIG. 20, an upper insulating layer 252 may be formed on the capping layer 236 and the interlayer insulating layer 246 in the cell array area CA and the peripheral circuit area PA.

In some embodiments, the upper insulating layer 252 may include a silicon nitride layer, but embodiments of the present disclosure are not limited thereto.

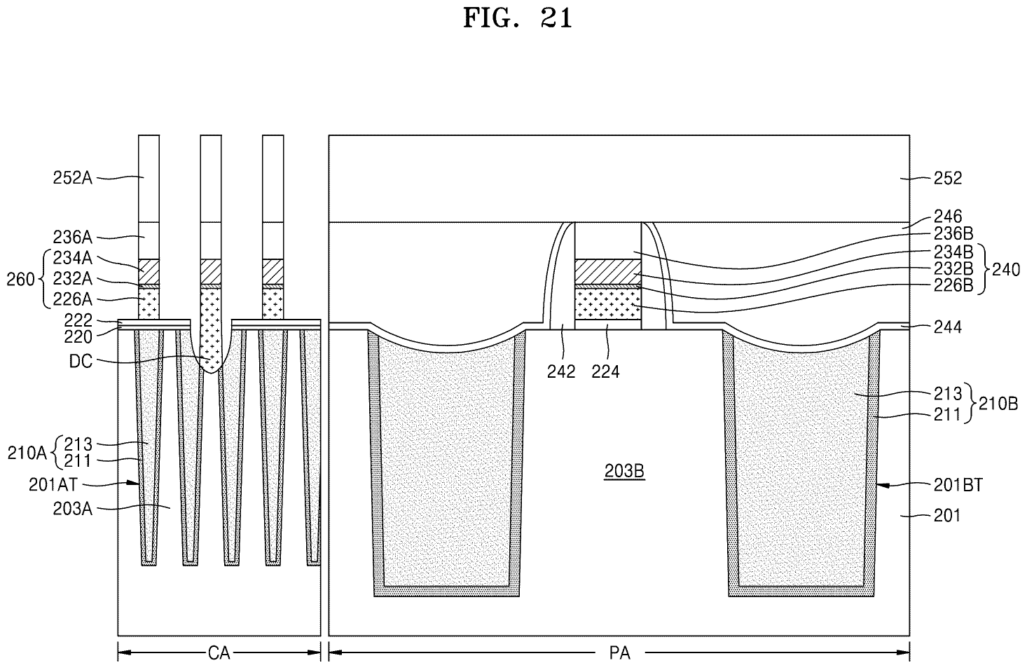

Referring to FIG. 21, a photolithography process may be used to pattern the upper insulating layer 252 and the capping layer 236.

As the result of the patterning, a cell mask pattern 252A, a capping pattern 236A, and a core mask pattern, which are to be used as an etch mask for forming a plurality of bit lines 260, may be formed in the cell array area CA.

The bit lines 260 may be formed in the cell array area CA by etching a portion of the lower structure by using the cell mask pattern 252A, the capping pattern 236A, and the core mask pattern as an etch mask.

More specifically, a plurality of bit lines 260 including the first conductive pattern 226A, the third conductive pattern 232A, and the fourth conductive pattern 234A may be formed in the cell array area CA by etching the exposed portions of the first conductive layer 226, the third conductive layer 232, and the fourth conductive layer 234 by using the cell mask pattern 252A, the capping pattern 236A, and the core mask pattern as an etch mask. The bit lines 260 may be connected to the first active area 203A of the substrate 201 through the direct contact DC.

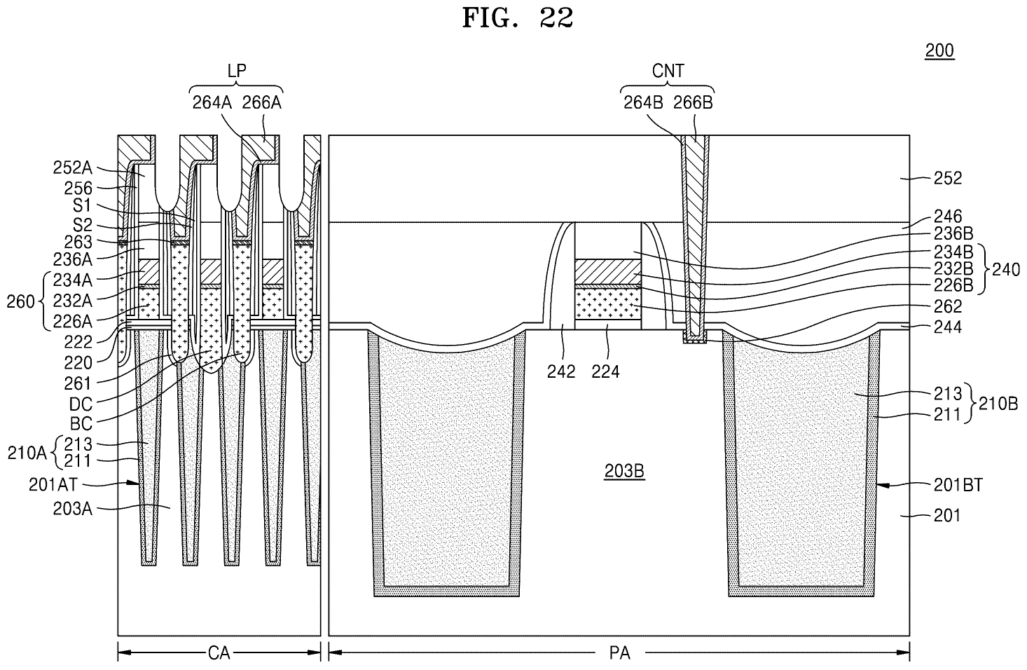

Referring to FIG. 22, a plurality of buried contacts BC and a plurality of conductive landing pads LP respectively connected to the buried contacts BC may be formed in a space between the bit lines 260 in the cell array area CA.

More specifically, insulating spacers S1 and S2 covering insulating liners 256 on sidewalls of the bit lines 260 may be formed in the cell array area CA. A plurality of insulating patterns defining a plurality of holes for forming the buried contacts BC in the space between the bit lines 260 may be formed. The first active area 203A of the substrate 201 may be exposed through the holes. A first metal silicide layer 261 may be formed on the surface of the first active area 203A that is exposed. Subsequently, the buried contacts BC connected to the first active area 203A may be formed by partially filling the lower portions of the holes.

In some embodiments, the first metal silicide layer 261 may include cobalt silicide, but embodiments of the present disclosure are not limited thereto. In some embodiments, the first metal silicide layer 261 may be omitted. The buried contacts BC may include doped polysilicon.

In some embodiments, the insulating spacers S1 and S2 may include a silicon oxide layer, a silicon nitride layer, air, or any combination thereof. A case where the insulating spacers S1 and S2 are each provided as a double layer is illustrated, but the insulating spacers S1 and S2 may be provided as a single layer or a triple layer. The insulating patterns may include a nitride layer, an oxide layer, or any combination thereof.

Subsequently, a third metal silicide layer 263 may be formed on the buried contacts BC inside the holes between the bit lines 260. In some embodiments, the third metal silicide layer 263 may include cobalt silicide, but embodiments of the present disclosure are not limited thereto. In some embodiments, the third metal silicide layer 263 may be omitted.

In addition, more specifically, a contact hole passing through a portion of the interlayer insulating layer 246 and the upper insulating layer 252 to expose the second active area 203B may be formed in the peripheral circuit area PA. A second metal silicide layer 262 may be formed on a surface of the second active area 203B exposed through the contact hole. In some embodiments, the second metal silicide layer 262 may include cobalt silicide, but embodiments of the present disclosure are not limited thereto. In some embodiments, the second metal silicide layer 262 may be omitted.

Subsequently, a conductive barrier layer and a conductive layer may be formed in the cell array area CA and the peripheral circuit area PA. The conductive barrier layer and the conductive layer may be etched back to expose the upper insulating layer 252.

As the result of the etch-back, in the cell array area CA, a portion of the conductive barrier layer and a portion of the conductive layer respectively remain as a first conductive barrier layer 264A and a first conductive layer 266A that cover the bit lines 260 to vertically overlap a portion of the bit lines 260 while filling the holes on the third metal silicide layer 263.

In addition, as the result of the etch-back, in the peripheral circuit area PA, a portion of the conductive barrier layer and a portion of the conductive layer remain as a second conductive barrier layer 264B and a second conductive layer 266B that fill the contact hole.

Subsequently, in the cell array area CA, a mask pattern exposing a portion of the first conductive layer 266A may be formed on the first conductive layer 266A. The first conductive barrier layer 264A, the first conductive layer 266A, and the insulating layers therearound may be etched by using the mask pattern as an etch mask to form a plurality of conductive landing pads LP from the remaining portions of the first conductive barrier layer 264A and the first conductive layer 266A. In the peripheral circuit area PA, the second conductive barrier layer 264B and the second conductive layer 266B inside the contact hole CH may constitute a contact plug CNT.

Subsequently, a plurality of capacitor structures electrically connectable to the conductive landing pads LP may be formed in the cell array area CA, and a multilayer wiring structure may be formed in the peripheral circuit area PA. In this manner, a semiconductor device 200 may be formed.

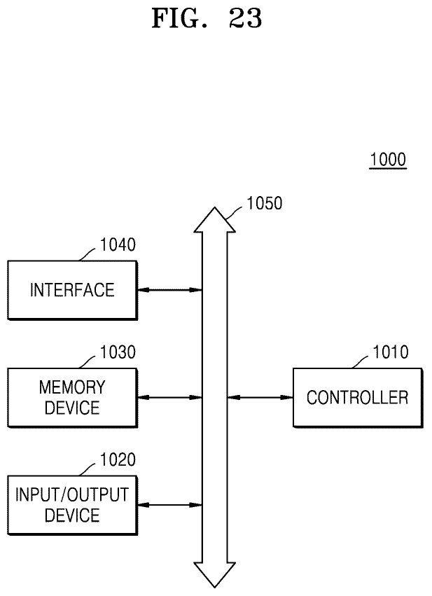

FIG. 23 is a configuration diagram illustrating a system including a semiconductor device, according to an embodiment.

Referring to FIG. 23, a system 1000 includes a controller 1010, an input/output device 1020, a memory device 1030, an interface 1040, and a bus 1050.

The system 1000 may be a mobile system or a system that transmits or receives information. In some embodiments, the mobile system may be a portable computer, a web tablet, a mobile phone, a digital music player, or a memory card.

The controller 1010 may be configured to control an execution program in the system 1000 and may include a microprocessor, a digital signal processor, a microcontroller, or devices similar thereto.

The input/output device 1020 may be used to input or output data to or from the system 1000. The system 1000 may be connected to an external device, for example, a personal computer or a network, by using the input/output device 1020 and may exchange data with the external device. The input/output device 1020 may be, for example, a touch screen, a touch pad, a keyboard, or a display.

The memory device 1030 may store data for the operation of the controller 1010 or store data processed by the controller 1010. The memory device 1030 may include the semiconductor device 200 manufactured by the method of manufacturing a semiconductor device, according to an embodiment of the present disclosure.

The interface 1040 may be a data transmission path between the system 1000 and the external device. The controller 1010, the input/output device 1020, the memory device 1030, and the interface 1040 may communicate with each other via the bus 1050.

While non-limiting example embodiments have been particularly shown and described, it will be understood that various changes in form and details may be made therein without departing from the spirit and scope of the present disclosure.

What is claimed is:

1. A method comprising:
forming a trench in a substrate;
conformally forming a first insulating layer on a top surface of the substrate and on an inner wall of the trench through a thermal oxidation process;
forming a second insulating layer on the first insulating layer through an atomic layer deposition process such that a portion of the second insulating layer is within the trench;
performing a dry etching process on the second insulating layer and the first insulating layer such as to expose the top surface of the substrate; and
forming a device isolation layer inside the trench, the device isolation layer including a first insulating pattern formed by etching the first insulating layer and a second insulating pattern formed by etching the second insulating layer,
wherein the device isolation layer has a round top surface.

2. The method of claim 1, wherein the performing the dry etching process comprises etching the first insulating layer at a first etch rate and etching the second insulating layer at a second etch rate, greater than the first etch rate.

3. The method of claim 2, wherein the performing the dry etching process further comprises controlling the first etch rate and the second etch rate based on a flow rate of process gas used in the dry etching process.

4. The method of claim 3, wherein the process gas includes fluorine (HF) gas and ammonia (NH₃) gas, and
wherein, in the dry etching process, a flow rate of the HF gas is greater than a flow rate of the NH₃ gas.

5. The method of claim 1, wherein the second insulating pattern is on an inner side of the first insulating pattern, and
wherein the round top surface of the device isolation layer is formed continuously through an outermost edge of the first insulating pattern, an interface between the first insulating pattern and the second insulating pattern, and the second insulating pattern.

6. The method of claim 5, wherein a vertical level of a top surface of the first insulating pattern of the device isolation layer is higher than a vertical level of a top surface of the second insulating pattern of the device isolation layer.

7. The method of claim 1, further comprising, after forming the device isolation layer, sequentially forming a high-k dielectric material layer and a conductive material layer on the round top surface of the device isolation layer and the top surface of the substrate.

8. The method of claim 7, further comprising removing the high-k dielectric material layer and the conductive material layer from the device isolation layer,
wherein residue of the conductive material layer does not remain in an area where the round top surface of the device isolation layer is in contact with the top surface of the substrate.

9. The method of claim 1, wherein the first insulating layer and the second insulating layer include a same material.

10. The method of claim 1, wherein the device isolation layer includes a shallow trench isolation.

11. A method of manufacturing a semiconductor device, the method comprising:
forming a plurality of trenches in each of a cell array area and a peripheral circuit area of a substrate;
conformally forming a first insulating layer on inner walls of the plurality of trenches and on a top surface of the substrate through a thermal oxidation process;
forming a second insulating layer on the first insulating layer through an atomic layer deposition process such that a portion of the second insulating layer is within the plurality of trenches;
forming a plurality of device isolation layers by performing a dry etching process on the second insulating layer and the first insulating layer such as to expose the top surface of the substrate;
sequentially forming a high-k dielectric material layer and a conductive material layer on top surfaces of the plurality of device isolation layers and the top surface of the substrate; and
patterning the high-k dielectric material layer and the conductive material layer,
wherein each of the plurality of device isolation layers formed in the peripheral circuit area have a round top surface.

12. The method of claim 11, wherein the performing the dry etching process comprises etching the first insulating layer at a first etch rate and etching the second insulating layer at a second etch rate, greater than the first etch rate, and
wherein the performing the dry etching process further comprises controlling the first etch rate and the second etch rate based on a flow rate of process gas used in the dry etching process.

13. The method of claim 12, wherein the process gas includes fluorine (HF) gas and ammonia (NH₃) gas, and
wherein, in the dry etching process, a flow rate of the HF gas is greater than a flow rate of the NH₃ gas.

14. The method of claim 11, wherein, in the patterning, residue of the conductive material layer does not remain on the round top surface of each of the plurality of device isolation layers formed in the peripheral circuit area and do not remain in an area where the round top surface of each of the plurality of device isolation layers are in contact with the top surface of the substrate.

15. The method of claim 11, wherein, in the peripheral circuit area, the high-k dielectric material layer forms a gate insulating layer, and the conductive material layer forms a gate electrode.

16. A method of manufacturing a semiconductor device, the method comprising:
forming a first device isolation and a second device isolation within a substrate, the substrate including:
a cell array area including a first active area defined by the first device isolation layer; and
a peripheral circuit area including a second active area defined by the second device isolation layer;
forming, in the cell array area, a word line crossing the first active area and a direct contact connected to the first active area;
forming, in the cell array area, a bit line structure connected to the direct contact and perpendicular to the word line; and
forming, in the peripheral circuit area, a peripheral circuit gate structure on the second active area,
wherein the forming the first device isolation layer and the second device isolation layer comprises:
forming trenches in each of the cell array area and the peripheral circuit area;
conformally forming a first insulating layer on inner walls of the trenches and a top surface of the substrate through a thermal oxidation process;
forming a second insulating layer on the first insulating layer through an atomic layer deposition process such as to fill the trenches; and
performing a dry etching process on the second insulating layer and the first insulating layer such as to expose the top surface of the substrate,
wherein the first device isolation layer has a flat top surface in the cell array area, and
wherein the second device isolation layer has a round top surface in the peripheral circuit area.

17. The method of claim 16, wherein a first width of the first device isolation layer in a horizontal direction is less than a second width of the second device isolation layer in the horizontal direction.

18. The method of claim 17, wherein the forming the second device isolation layer comprises:
forming a first insulating pattern by etching the first insulating layer; and
forming a second insulating pattern, on an inner side of the first insulating pattern, by etching the second the second insulating layer, and
wherein a vertical level of a top surface of the first insulating pattern of the second device isolation layer is higher than a vertical level of a top surface of the second insulating pattern of the second device isolation layer.

19. The method of claim 16, wherein the performing the dry etching process further comprises performing the dry etching process using a predetermined selectivity ratio of a first etch rate of the first insulating layer to a second etch rate of the second insulating layer.

20. The method of claim 19, wherein the performing the dry etching process further comprises etching the first insulating layer at the first etch rate and etching the second insulating layer at the second etch rate, the second etch rate being greater than the first etch rate,
wherein the performing the dry etching process further comprises controlling the first etch rate and the second etch rate based on a flow rate of process gas used in the dry etching process,
wherein the process gas includes fluorine (HF) gas and ammonia (NH₃) gas, and
wherein, in the dry etching process, a flow rate of the HF gas is greater than a flow rate of the NH₃ gas.
